(19) United States
(12) Patent Application Publication
(10) Pub. No.: US 2024/0421129 A1
(43) Pub. Date: Dec. 19, 2024

(54) SEMICONDUCTOR PACKAGE

(71) Applicant: Samsung Electronics Co., Ltd., Suwon-si (KR)

(72) Inventor: SEUNGDUK BAEK, Suwon-si (KR)

(21) Appl. No.: 18/403,242

(22) Filed: Jan. 3, 2024

(30) Foreign Application Priority Data
Jun. 19, 2023 (KR) 10-2023-0078221

(51) Int. Cl. H01L 25/065; H01L 23/00; H01L 23/31; H10B 80/00

(52) U.S. Cl. CPC H01L 25/0657; H01L 23/3185; H01L 24/08; H01L 24/16; H01L 24/32; H01L 24/73; H01L 24/97; H01L 25/0652; H10B 80/00; H01L 2224/08145; H01L 2224/16145; H01L 2224/16227; H01L 2224/32145; H01L 2224/32225; H01L 2224/73204; H01L 2224/97; H01L 2225/06513; H01L 2225/06541; H01L 2924/1431; H01L 2924/1436

(57) ABSTRACT

A semiconductor package include a buffer die, a computing die on the buffer die, a plurality of memory dies vertically stacked on each other to form a memory stack, wherein the memory stack is disposed on the computing die, wherein the buffer die, the computing die, and the memory stack are vertically stacked on each other, and wherein the computing die is disposed in a space between the buffer die and the memory stack, and a mold layer covering the computing die and the plurality of memory dies. The buffer die comprises a plurality of outer connection members. The computing die comprises a plurality of computing blocks. Each of the plurality of memory dies comprises a plurality of memory blocks. The plurality of computing blocks are configured to process data received from the plurality of memory blocks and to store the processed results in the plurality of memory blocks.

### CROSS-REFERENCE TO RELATED APPLICATIONS

This U.S. non-provisional patent application claims priority under 35 U.S.C. § 119 to Korean Patent Application No. 10-2023-0078221, filed on Jun. 19, 2023, in the Korean Intellectual Property Office, the entire contents of which are hereby incorporated by reference.

### BACKGROUND OF THE INVENTION

The present disclosure relates to a semiconductor package, and in particular, to a stack-type semiconductor package.

A semiconductor package facilitates the use of an integrated circuit chip as a component in an electronic product. The semiconductor package includes a printed circuit board (PCB) and a semiconductor chip die, which is mounted on the PCB and is electrically connected to the PCB using bonding wires or bumps. With development of the electronic industry, many studies are being conducted to improve reliability and durability of the semiconductor package.

### SUMMARY

An aspect of the present disclosure provides a highly efficient high-performance semiconductor package.

An aspect of the present disclosure provides a method of improving quality and yield of a semiconductor package in a process of fabricating the semiconductor package.

According to an aspect of the present disclosure, a semiconductor package include a buffer die, a computing die on the buffer die, a plurality of memory dies vertically stacked on each other to form a memory stack, wherein the memory stack is disposed on the computing die, wherein the buffer die, the computing die, and the memory stack are vertically stacked on each other, and wherein the computing die is disposed in a space between the buffer die and the memory stack, and a mold layer covering the computing die and the plurality of memory dies. The buffer die comprises a plurality of outer connection members. The computing die comprises a plurality of computing blocks. Each of the plurality of memory dies comprises a plurality of memory blocks. The plurality of computing blocks are configured to process data received from the plurality of memory blocks and to store the processed results in the plurality of memory blocks.

According to an aspect of the present disclosure, a semiconductor package includes a buffer die, a computing die on the buffer die, a plurality of memory dies stacked on the computing die, and a mold layer covering the computing die and memory dies. The buffer die comprises a plurality of outer connection members. The computing die comprises a plurality of computing blocks. Each of the plurality of memory dies comprises a plurality of memory blocks. The plurality of computing blocks are configured to process data received from the plurality of memory blocks and to store the processed results in the plurality of memory blocks. The buffer die further comprises a first semiconductor substrate, on which the plurality of outer connection members are disposed, and a plurality of first upper conductive pads disposed at a top surface of the first semiconductor substrate. The computing die further comprises a second semiconductor substrate, at which the plurality of computing blocks are disposed, a second interlayer insulating layer covering the second semiconductor substrate, and a plurality of second lower conductive pads disposed at a bottom surface of the second interlayer insulating layer and are connected to the buffer die. The plurality of first upper conductive pads contact the plurality of second lower conductive pads, respectively. The plurality of memory dies comprise first to fourth memory dies which are vertically stacked on each other. The buffer die has a first thickness. The computing die has a second thickness. Each of the first to third memory dies has a third thickness. The first thickness is larger than the second thickness. The third thickness is smaller than a sum of the first and second thicknesses.

According to an aspect of the present disclosure, a semiconductor package includes a package substrate, an interposer substrate on the package substrate, and a first semiconductor chip, a second semiconductor chip, and a third semiconductor chip, which are disposed on the interposer substrate and are horizontally arranged in a first direction. The first semiconductor chip includes a first buffer die, a first computing die vertically disposed on the first buffer die, a plurality of first memory dies vertically stacked on each other to form a first memory stack, wherein the first memory stack is disposed on the first computing die, wherein the first buffer die, the first computing die, and the first memory stack are vertically stacked on each other, and where the first computing die is disposed in a space between the first buffer die and the first memory stack, and a first mold layer covering the first computing die and the plurality of first memory dies. The first buffer die comprises a plurality of first outer connection members. The first computing die comprises a plurality of first computing blocks. Each of the plurality of first memory dies comprises a plurality of first memory blocks. The plurality of first computing blocks are configured to process data received from the plurality of first memory blocks and to store the processed results in the plurality of first memory blocks.

According to an aspect of the present disclosure, a method of fabricating a semiconductor package includes providing a buffer die wafer including a plurality of first penetration vias, forming a plurality of first upper conductive pads contacting the plurality of first penetration vias and disposed at a top surface of the buffer die wafer, forming a plurality of first lower conductive pads disposed at a bottom surface of the buffer die wafer, bonding a carrier substrate to the bottom surface of the buffer die wafer using an adhesive member, providing a computing die wafer including a plurality of second penetration vias, forming a plurality of second upper conductive pads contacting the plurality of second penetration vias and disposed at a top surface of the computing die wafer, forming a plurality of second lower conductive pads disposed at a bottom surface of the computing die wafer, bonding the computing die wafer to the buffer die wafer, such that the plurality of first upper conductive pads contact the plurality of second lower conductive pads, using a hybrid copper bonding method, providing a plurality of memory dies, wherein each of the plurality of memory dies include a plurality of third penetration vias, forming a plurality of third upper conductive pads contacting the plurality of third penetration vias of each of the plurality of memory dies and disposed at a top surface of each of the plurality of memory dies, forming a plurality of third lower conductive pads disposed at a bottom surface of each of the plurality of memory dies, bonding the plurality of memory dies to the computing die wafer, such that the plurality of second upper conductive pads of the computing die contact the plurality of third lower conductive pads of a lowermost memory die of the plurality of memory dies, using a hybrid copper bonding method, forming a molding member to cover the top surface of the computing die wafer and side surfaces of the plurality of memory dies, and separating the carrier substrate and the adhesive member from the buffer die wafer.

### BRIEF DESCRIPTION OF THE DRAWINGS

FIG. 1A is a sectional view illustrating a semiconductor package according to an embodiment of the inventive concept.

FIGS. 1B and 1C are enlarged sectional views illustrating a portion ‘P1’ of FIG. 1A.

FIG. 2A is a plan view illustrating a computing die according to an embodiment of the inventive concept.

FIG. 2B is a plan view illustrating a first memory die according to an embodiment of the inventive concept.

FIG. 3 is an enlarged sectional view illustrating a portion ‘P2’ of FIG. 1A.

FIG. 4 is an enlarged sectional view illustrating a portion ‘P3’ of FIG. 1A.

FIGS. 5A and 5B are enlarged sectional views illustrating a portion ‘P4’ of FIG. 1A.

FIGS. 6A to 6G are sectional views sequentially illustrating a process of fabricating the semiconductor package of FIG. 1A.

FIG. 7 is a plan view illustrating a semiconductor package according to an embodiment of the inventive concept.

FIG. 8 is a sectional view taken along line C-C′ of FIG. 7 to illustrate a semiconductor package according to an embodiment of the inventive concept.

FIG. 9 is a sectional view taken along the line C-C′ of FIG. 7 to illustrate a semiconductor package according to an embodiment of the inventive concept.

FIG. 10 is a sectional view of the fourth peripheral semiconductor chip of FIG. 9 according to an embodiment of the inventive concept.

FIG. 11 is a sectional view of the fourth peripheral semiconductor chip of FIG. 9 according to an embodiment of the inventive concept.

FIG. 12 is a plan view illustrating an example of a memory die of FIG. 11 according to an embodiment of the present disclosure.

### DETAILED DESCRIPTION

Example embodiments of the inventive concepts will now be described more fully with reference to the accompanying drawings, in which example embodiments are shown.

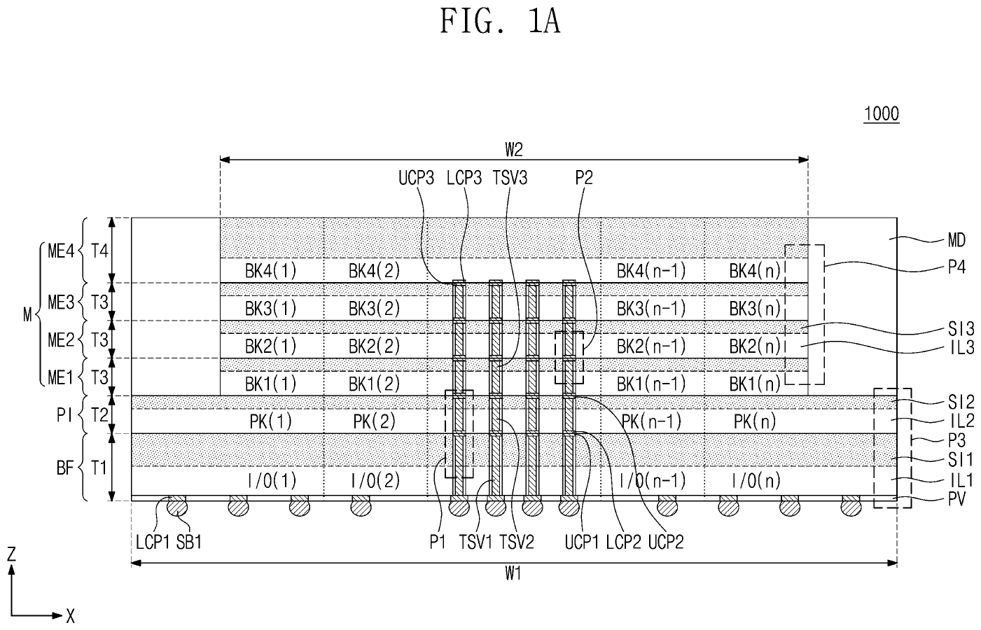

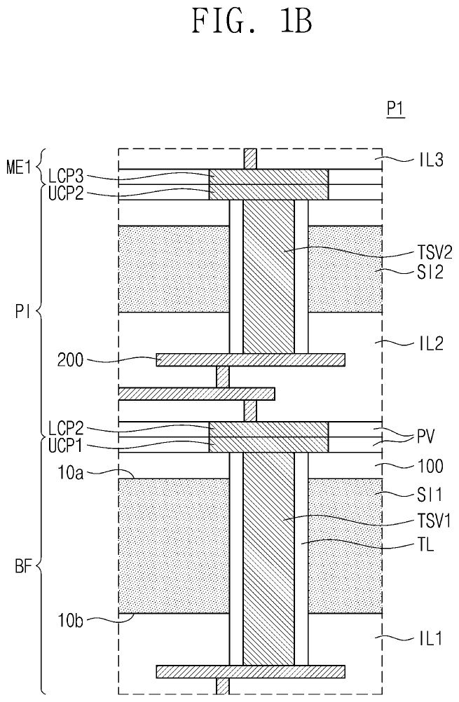

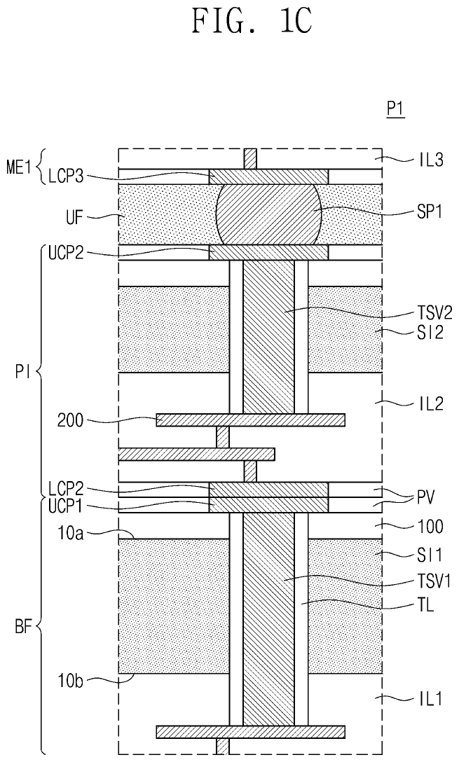

FIG. 1A is a sectional view illustrating a semiconductor package according to an embodiment of the inventive concept. FIGS. 1B and 1C are enlarged sectional views illustrating a portion ‘P1’ of FIG. 1A.

Referring to FIGS. 1A to 1C, a semiconductor package 1000 may include a buffer die BF, a computing die PI disposed on the buffer die BF, and a plurality of memory dies M stacked on the computing die PI. In an embodiment, the memory dies M may be vertically stacked on each other to form a memory stack. The memory dies M may include a first memory die ME1, a second memory die ME2, a third memory die ME3, and a fourth memory die ME4. For example, the semiconductor package 1000 may be a processing in memory (PIM) chip or a high bandwidth memory-processing in memory (HBM-PIM) chip that has both a memory function for data storage and a processor function for computing operations. The first memory die ME1 may include a plurality of first memory blocks BK1(1) to BK1(n). The second memory die ME2 may include a plurality of second memory blocks BK2(1) to BK2(n). The third memory die ME3 may include a plurality of third memory blocks BK3(1) to BK3(n). The fourth memory die ME4 may include a plurality of fourth memory blocks BK4(1) to BK4(n). In an embodiment, the first memory blocks BK1(1) to BK1(n), the second memory blocks BK2(1) to BK2(n), the third memory blocks BK3(1) to BK3(n), and the fourth memory blocks BK4(1) to BK4(n) may vertically overlap each other, respectively.

The buffer die BF, the computing die PI, and the memory dies M may include semiconductor substrates SI1 to SI3 and interlayer insulating layers IL1 to IL3.

As shown in FIGS. 1B and 1C, each of the semiconductor substrates SI1 to SI3 may include a first surface 10a and a second surface 10b, which are opposite to each other. Each of the semiconductor substrates SI1 to SI3 may be a single-crystalline semiconductor substrate or a silicon-on-insulator (SOI) substrate. The interlayer insulating layers IL1 to IL3 may cover the second surfaces 10b of the semiconductor substrates SI1 to SI3, respectively. The first surfaces 10a of the semiconductor substrates SI1 to SI3 and the interlayer insulating layers IL1 to IL3 may be covered with passivation layers PV, respectively. The interlayer insulating layers IL1 to IL3 may be formed of or include at least one of silicon oxide, silicon nitride, silicon oxynitride, and a porous insulating material and may have a single- or multi-layered structure. The passivation layers PV may be formed of or include at least one of silicon oxide, silicon nitride, and silicon carbon nitride (SiCN) and may have a single- or multi-layered structure.

The buffer die BF, the computing die PI, the first memory die ME1, the second memory die ME2, and the third memory die ME3 may include penetration vias TSV1 to TSV3. The penetration vias TSV1 to TSV3 may be provided to penetrate the semiconductor substrates SI1 to SI3 of the buffer die BF, the computing die PI, the first memory die ME1, the second memory die ME2, and the third memory die ME3. Via insulating layers TL may be interposed between the penetration vias TSV1 to TSV3 and the semiconductor substrates SI1 to SI3. The penetration vias TSV1 to TSV3 may be formed of or include at least one of metallic materials such as copper, aluminum, and tungsten. The via insulating layer TL may be formed of or include at least one of silicon oxide, silicon nitride, or silicon oxynitride and may have a single- or multi-layered structure. The via insulating layer TL may include an air gap region. The term “air gap” may include gaps (e.g., pockets) of air or gases other than air, such as other atmospheric gases or chamber gases that may be present during manufacturing. An “air gap” may also constitute a space having no or substantially no gas or other material therein. The interlayer insulating layers IL1 to IL3 may cover the penetration vias TSV1 to TSV3. For example, the penetration vias TSV1 to TSV3 may penetrate the interlayer insulating layers IL1 to IL3, respectively. The fourth memory die ME4 may not include a penetration via such as the first to third penetration vias TS1 to TSV3.

Inner interconnection lines 200 may be disposed in the interlayer insulating layers IL1 to IL3 to form a multi-layered structure. The inner interconnection lines 200 may be formed of or include at least one of copper, aluminum, tungsten, titanium, titanium nitride, tantalum, tantalum nitride, ruthenium, or iridium and may have a single- or multi-layered structure. The inner interconnection lines 200 may be respectively connected to the penetration vias TSV1 to TSV3, which are provided to penetrate corresponding ones of the dies BF, PI, and ME1 to ME3.

Lower conductive pads LCP1 to LCP3 may be respectively disposed under bottom surfaces of the interlayer insulating layers IL1 to IL3 of the buffer die BF, the computing die PI, the first memory die ME1, the second memory die ME2, the third memory die ME3, and the fourth memory die ME4. For example, first lower conductive pads LCP1 may be disposed at a bottom surface of the first interlayer insulating layer IL1 in the buffer die BF, second lower conductive pads LCP2 may be disposed at a bottom surface of the second interlayer insulating layer IL2 in the computing die PI, and third lower conductive pads LCP3 may be disposed at a bottom surface of the third interlayer insulating layer IL3 of each of the first to fourth memory dies ME1 to ME4. Upper conductive pads UCP1 to UCP3 may be respectively disposed on top surfaces of the semiconductor substrates SI1 to SI3 of the buffer die BF, the computing die PI, the first memory die ME1, the second memory die ME2, and the third memory die ME3. For example, first upper conductive pads UCP1 may be disposed at a top surface of the first semiconductor substrate SI1 in the buffer die BF, second upper conductive pads UCP2 may be disposed at a top surface of the second semiconductor substrate SI2 in the computing die PI, and third upper conductive pads UCP3 may be disposed at a top surface of the third semiconductor substrate SI3 in each of the first to third memory dies ME1 to ME3. In an embodiment, the lower conductive pads LCP1 to LCP3 and the upper conductive pads UCP1 to UCP3 may be formed of or include at least one of metallic materials such as copper (Cu), gold (Au), nickel (Ni), tin (Sn), silver (Ag), tungsten (W), and aluminum (Al). First outer connection members SB1 may be bonded to some of the first lower conductive pads LCP1 of the buffer die BF. In an embodiment, each of the first outer connection members SB1 may be bonded to a corresponding one of the first lower conductive pads LCP1 of the buffer die BF. The first outer connection members SB1 may include or may be at least one of copper bumps, copper pillars, and solder balls.

A bottom surface of the buffer die BF may be an active surface. The active surface refers to the part of the buffer die BF where electronic components or devices such as transistors are fabricated. This region is actively involved in the operation of the buffer die BF and performs various functions such as amplification, switching, and signal processing to carry out logical or analog functions of the buffer die BF. In an embodiment, the buffer die BF may be provided in a face down manner. The buffer die BF may include a first semiconductor substrate SI1, a first interlayer insulating layer IL1, input/output terminals I/O, and first penetration vias TSV1. In an embodiment, the input/output terminals I/O may include first outer connection members SB1. The first outer connection members SB1 may be grouped into a plurality of input/out terminals I/O (i.e., a plurality of input/output terminal groups IO(1) to IO(n)). The input/output terminals I/O will be described below.

The first semiconductor substrate SI1 may be a wafer-level semiconductor substrate made of a semiconductor material, such as silicon (Si). For example, the first semiconductor substrate SI1 may be a single-crystalline semiconductor substrate or a silicon-on-insulator (SOI) substrate. The input/output terminals I/O may be provided on the first semiconductor substrate SI1. The first interlayer insulating layer IL1 may cover the input/output terminals I/O and the first semiconductor substrate SI1. For example, when viewed in a plan view, the first interlayer insulating layer IL1 may overlap the first semiconductor substrate SI1 and the input/output terminals I/O.

The buffer die BF may be a base die including a semiconductor device. In an embodiment, the buffer die BF may serve as an interface die, a logic die, a master die, or the like. The die may be referred to as a chip. The buffer die BF may include an interface circuit which serves to facilitate communication between an external controller and the computing and memory dies PI and M. The buffer die BF may be configured to receive commands, data, and/or signals, which are transmitted from the external controller, and to transmit the received commands, data, and/or signals, to the computing and memory dies PI and M through the penetration vias TSV1 to TSV3. The first penetration vias TSV1 of the buffer die BF may be provided to penetrate the first semiconductor substrate SI1 and may be connected to the computing die PI. The buffer die BF may be configured to transmit data, which are output from the computing and memory dies PI and M, to the external controller through the input/output terminals I/O. In an embodiment, an interposer substrate or a package substrate may be provided in place of the buffer die BF.

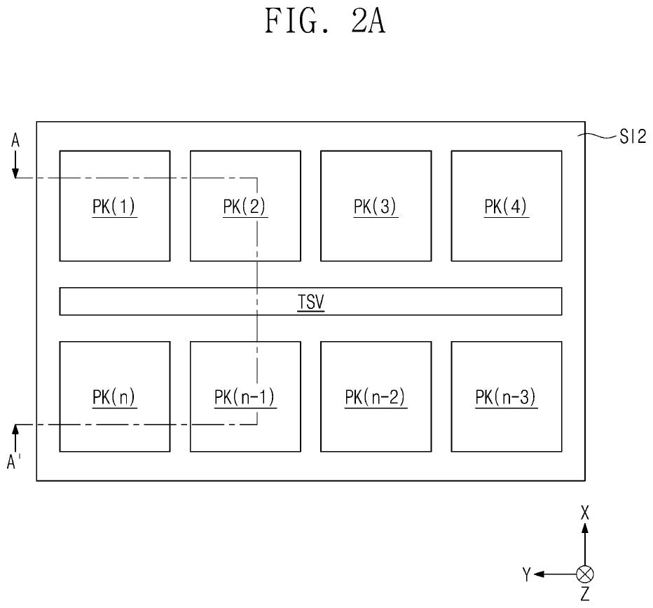

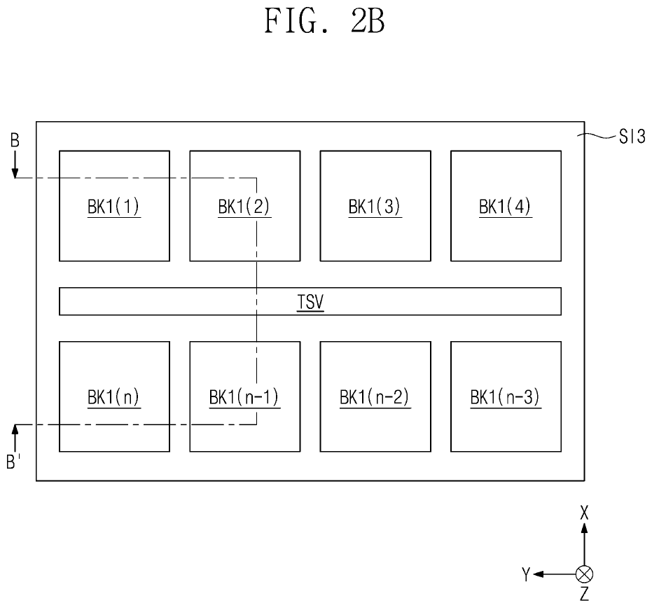

FIG. 2A is a plan view illustrating a computing die according to an embodiment of the inventive concept. A section taken along a line A-A′ of FIG. 2A may correspond to the computing die PI of FIG. 1A.

Referring to FIGS. 1A and 2A, the computing die PI may include a second semiconductor substrate SI2, a second interlayer insulating layer IL2, computing blocks PK, and second penetration vias TSV2. In an embodiment, n computing blocks PK and a penetration via region TSV may be disposed on the second semiconductor substrate SI2 of the computing die PI. Here, the n is a natural number that is equal to or greater than 4. The computing blocks PK may be provided to enclose the penetration via region TSV. In an embodiment, the computing blocks PK may include first to nₜₕ computing blocks PK(1) to PK(n). The first to nth computing blocks PK(1) to PK(n) may be arranged in two rows extending in a third direction Y, and when viewed in a plan view, the penetration via region TSV may be disposed in a space between the two rows of the first to nth computing blocks PK(1) to PK(n).

A bottom surface of the computing die PI may be an active surface. The active surface refers to the part of the computing die PI where electronic components or devices such as transistors are fabricated. This region is actively involved in the operation of the computing die PI and performs various functions such as amplification, switching, and signal processing to carry out logical or analog functions of the computing die PI. For example, the computing die PI may be provided in a face-down way such that the active surface thereof contacts the buffer die BF. In an embodiment, the computing die PI and the buffer die BF may be provided to form a wafer-on-wafer (WOW) structure. The buffer die BF and the computing die PI may contact each other or may be close to each other, and thus an electrical signal distance between the buffer die BF and the computing die PI may be reduced and may realize a highly efficient semiconductor package.

FIG. 2B is a plan view illustrating a first memory die according to an embodiment of the inventive concept. A section taken along a line B-B′ of FIG. 2B may correspond to the first memory die ME1 of FIG. 1A.

Referring to FIGS. 1A and 2B, each of the first to fourth memory dies ME1 to ME4 may include a third semiconductor substrate SI3, a third interlayer insulating layer IL3, third lower conductive pads LCP3, a protection layer 100, and the passivation layer PV. Each of the first to third memory dies ME1 to ME3 may further include a third penetration via TSV3, the via insulating layer TL, and third upper conductive pads UCP3.

In an embodiment, the first memory die ME1, the second memory die ME2, the third memory die ME3, and the fourth memory die ME4 may be dynamic random access memory (DRAM) dies.

Referring to FIGS. 1A and 2B, each of the first, second, third, and fourth memory dies ME1, ME2, ME3, and ME4 may include n memory blocks BK1 to BK4. Here, the n is a natural number that is equal to or greater than 4. The number of the memory blocks in each memory die may vary from die to die. Each of the memory blocks BK1 to BK4 may be a memory bank which corresponds to a portion of a memory array of each memory die that can be accessed independently. For example, the memory array may be divided into multiple banks, and each bank can be accessed independently of the others so that multiple memory operations such as a read operation, a write operation, and a refresh operation can be performed simultaneously. The memory blocks BK1 to BK4 may be disposed on the third semiconductor substrates SI3 of the corresponding memory dies ME1 to ME4, respectively.

In an embodiment, as shown in FIG. 2B, n memory blocks BK1 and the penetration via region TSV may be disposed on the third semiconductor substrate SI3 of the first memory die ME1. The memory blocks BK1 may enclose the penetration via region TSV. In an embodiment, the memory blocks BK1 may include first to nₜₕ memory blocks BK1(1) to BK1(n). The first to nₜₕ memory blocks BK1(1) to BK1(n) may be arranged in two rows extending in a third direction Y, and when viewed in a plan view, the penetration via region TSV may be disposed in a space between the two rows of the first to nₜₕ memory blocks BK1(1) to BK1(n). However, the planar structure and disposition of the first memory die ME1 may not be limited to the example of FIG. 2B and may be variously changed. Each of the second to fourth memory dies ME2 to ME4 may also have the same or similar structure as the first memory die ME1 as described with reference to FIG. 2B.

The computing blocks PK of the computing die PI may or may not overlap the first memory blocks BK1 of the first memory die ME1, respectively. The computing blocks PK of the computing die PI may be configured to process data, which are received from the memory blocks BK1 to BK4 of the first to fourth memory dies ME1 to ME4, and store the results in the memory blocks BK1 to BK4 of the first to fourth memory dies ME1 to ME4. The computing die PI, which includes the computing blocks PK, may be separately disposed outside the memory dies M, and in this case, it may be possible to reduce a planar size of the memory die M and address technical issues such as the reduction in capacity of the memory dies M. For example, the computing blocks PK may be separately disposed in the computing die PI from the memory dies M, and thus the planar sizes of the memory dies may be reduced with an increasing memory capacity. The memory dies M may not have a functional block which performs an operation which is performed by the computing die PI.

A mold layer MD may be disposed on the computing die PI. The first, second, third, and fourth memory dies ME1, ME2, ME3, and ME4 may have side surfaces that are covered with the mold layer MD. The mold layer MD may be formed of or include an insulating resin (e.g., epoxy molding compound (EMC)). The mold layer MD may further include fillers dispersed in the insulating resin. The filler may be formed of or include silicon oxide (SiO₂).

In an embodiment, both of the buffer die BF and the computing die PI may have a first width W1 in a first direction X. All of the first to fourth memory dies ME1 to ME4 may have a second width W2 in the first direction X. For example, the first to fourth memory dies ME1 to ME4 may have the same width of the second width W2 in the first direction X. The second width W2 may be smaller than the first width W1.

The buffer die BF may have a first thickness T1 in a second direction Z, and the computing die PI may have a second thickness T2 in the second direction Z. The first thickness T1 may be larger than the second thickness T2. The first to third memory dies ME1 to ME3 may have a third thickness T3 in the second direction Z, and the fourth memory die ME4 may have a fourth thickness T4 larger than the third thickness T3. The third thickness T3 may be smaller than the sum of the first and second thicknesses T1 and T2.

Referring back to FIG. 1B, the first upper conductive pads UCP1 of the buffer die BF may contact the second lower conductive pads LCP2 of the computing die PI, respectively. The term “contact,” as used herein, refers to a direct connection (i.e., physical touching) unless the context indicates otherwise. The passivation layer PV of the buffer die BF may contact the passivation layer PV of the computing die PI. The first upper conductive pads UCP1 and the second lower conductive pads LCP2 may be formed of or include the same metallic material such as copper (Cu), gold (Au), nickel (Ni), tin (Sn), silver (Ag), tungsten (W), aluminum (Al), and a combination thereof. The computing blocks PK of the computing die PI may be placed on and connected to the input/output terminals I/O of the buffer die BF by using direct connections between the first upper conductive pads UCP1 and the second lower conductive pads LCP2, and in this case, a signal distance between the computing blocks PK of the computing die PI and the input/output terminals I/O of the buffer die BF may be reduced to increase the processing or operation speed of the semiconductor package.

The second upper conductive pads UCP2 of the computing die PI may contact the third lower conductive pads LCP3 of the first memory die ME1, respectively. The second upper conductive pads UCP2 and the third lower conductive pads LCP3 may be formed of or include the same metallic material such as copper (Cu), gold (Au), nickel (Ni), tin (Sn), silver (Ag), tungsten (W), aluminum (Al), and a combination thereof. Since the first memory blocks BK1 of the first memory die ME1 are placed on and connected to the computing blocks PK of the computing die PI by using direct connections between the second upper conductive pads UCP2 and the third lower conductive pads LCP3, a signal distance between the first memory blocks BK1 of the first memory die ME1 and the computing blocks PK of the computing die PI may be reduced, and this may make it possible to increase the processing or operation speed of the semiconductor package. In an embodiment, adjacent ones of the upper and lower conductive pads UCP1 to UCP3 and LCP1 to LCP3 may be fused to form a single object. In this case, there may be no observable interface between the adjacent ones of the upper and lower conductive pads UCP1 to UCP3 and LCP1 to LCP3.

In an embodiment, as shown in FIG. 1C, first inner connection members SP1 may be provided between the second upper conductive pads UCP2 of the computing die PI and the third lower conductive pads LCP3 of the first memory die ME1. For example, each of the first inner connection members SP1 may electrically connect a corresponding one of the second upper conductive pads UCP2 of the computing die PI to a corresponding one of the third lower conductive pads LCP3 of the first memory die ME1. Furthermore, an under fill UF may be provided to fill a space between the computing die PI and the first memory die ME1. The under fill UF may be formed through a dispensing and curing process. The under fill UF may be formed of or include an epoxy resin and may protect the first inner connection members SP1. The second upper conductive pads UCP2 and the third lower conductive pads LCP3 may be formed of or include the same metallic material such as copper (Cu), gold (Au), nickel (Ni), tin (Sn), silver (Ag), tungsten (W), aluminum (Al), and a combination thereof.

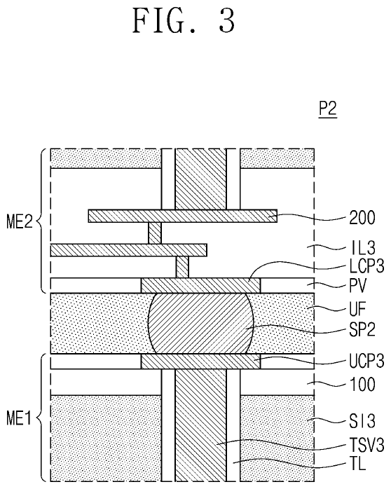

FIG. 3 is an enlarged sectional view illustrating a portion ‘P2’ of FIG. 1A. For example, FIG. 3 is an enlarged sectional view exemplarily illustrating a bonding structure between the first and second memory dies ME1 and ME2, which are two adjacent dies of the first to fourth memory dies ME1 to ME4.

In an embodiment, as shown in FIG. 3, second inner connection members SP2 may be provided between the third upper conductive pads UCP3 of the first memory die ME1 and the third lower conductive pads LCP3 of the second memory die ME2. For example, each of the second inner connection members SP2 may electrically connect a corresponding one of the third upper conductive pads UCP3 of the first memory die ME1 to a corresponding one of the third lower conductive pads LCP3 of the second memory die ME2. In addition, the under fill UF may be provided to fill a space between the first memory die ME1 and the second memory die ME2. The under fill UF may be formed through a dispensing and curing process. The under fill UF may be formed of or include an epoxy resin and may protect the second inner connection members SP2. The second upper conductive pads UCP2 and the third lower conductive pads LCP3 may be formed of or include the same metallic material such as copper (Cu), gold (Au), nickel (Ni), tin (Sn), silver (Ag), tungsten (W), aluminum (Al), and a combination thereof.

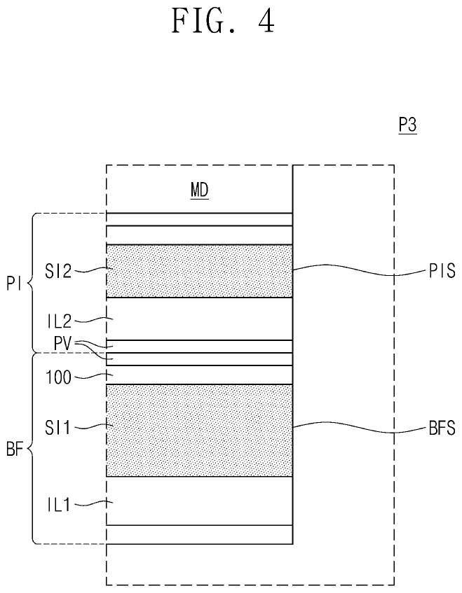

FIG. 4 is an enlarged sectional view illustrating a portion ‘P3’ of FIG. 1A.

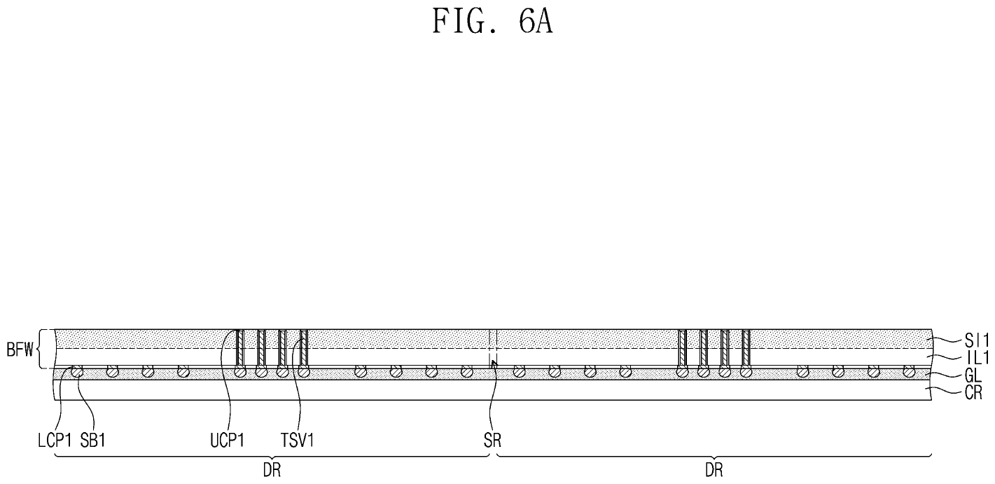

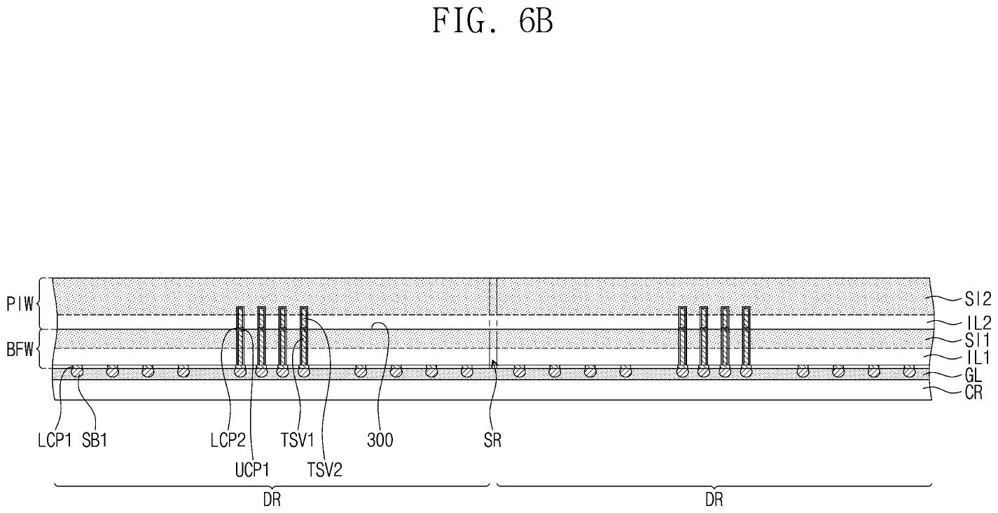

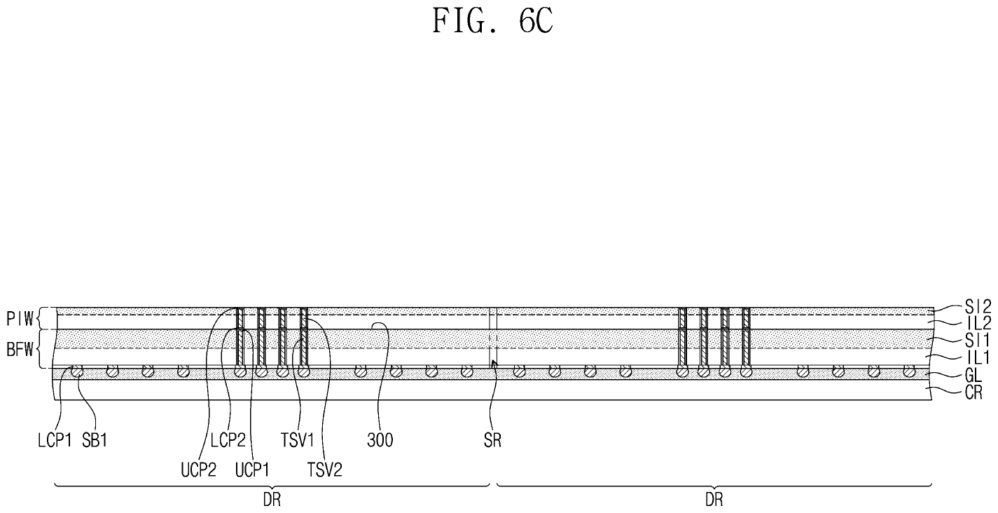

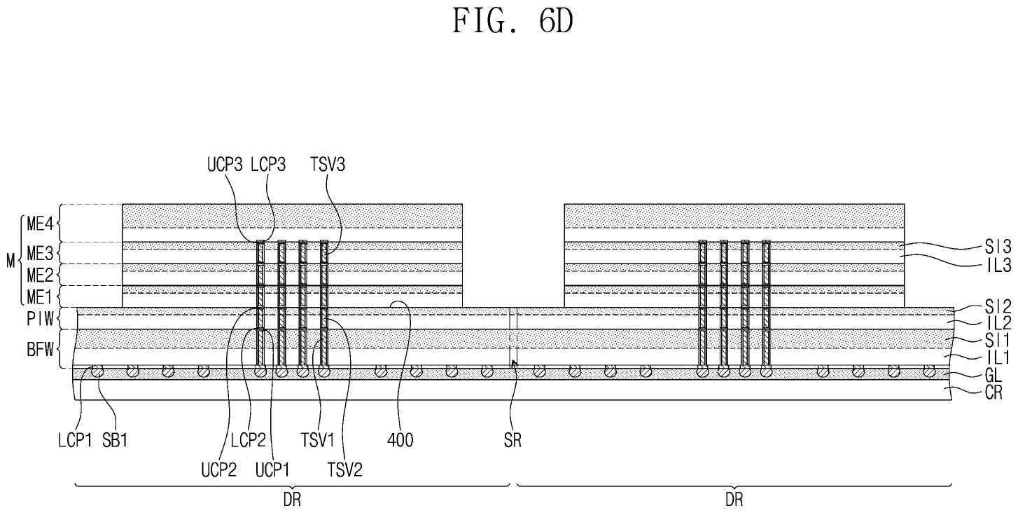

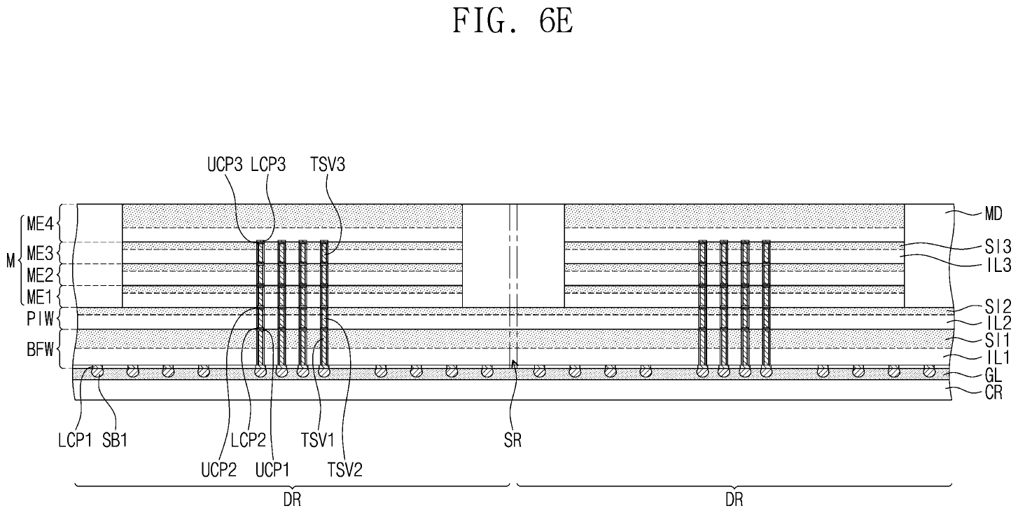

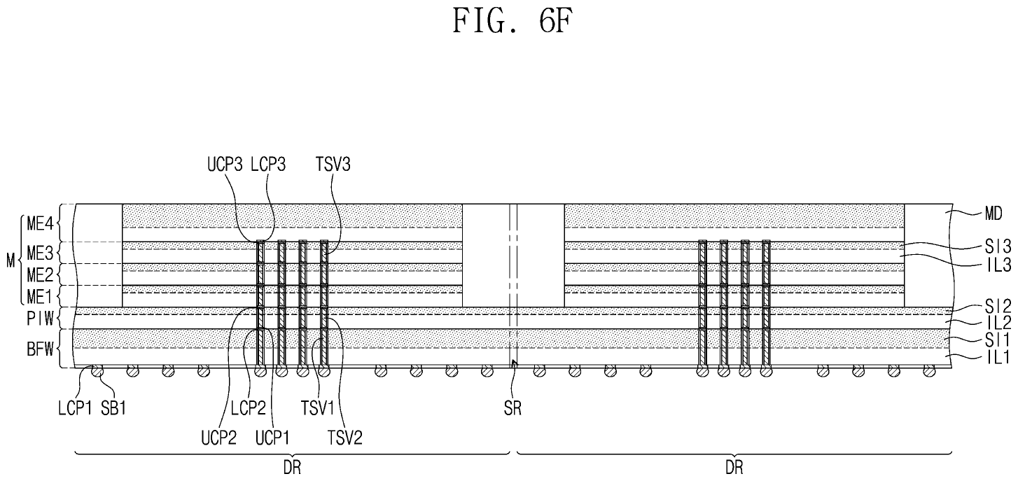

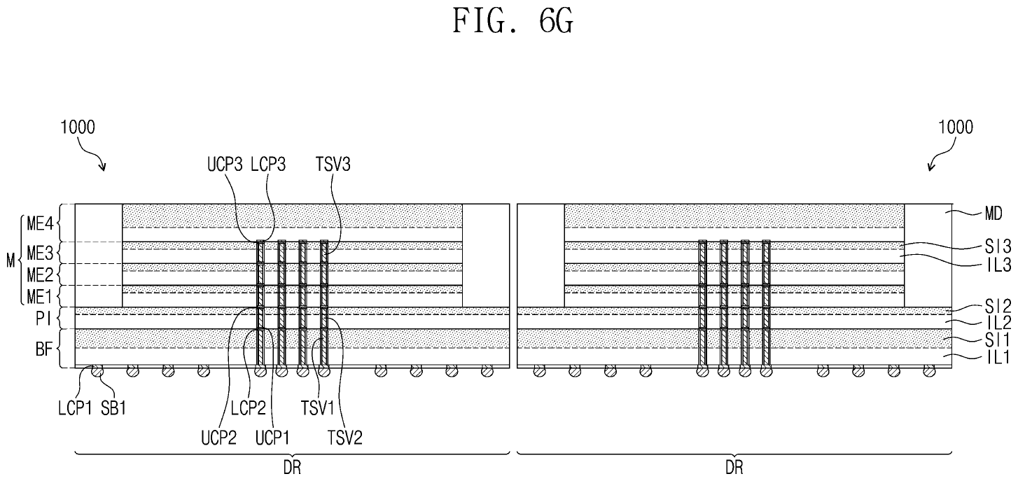

Referring to FIG. 4, the buffer die BF may be provided to have a side surface BFS that is vertically aligned to a side surface PIS of the computing die PI. For example, in the fabrication process of the semiconductor package 1000, a buffer die wafer BFW and a computing die wafer PIW may be bonded with each other in a wafer-on-wafer (WOW) structure and may be cut together by a sawing process of FIG. 6G, and in this case, the semiconductor package may have the same structure as shown in FIG. 4.

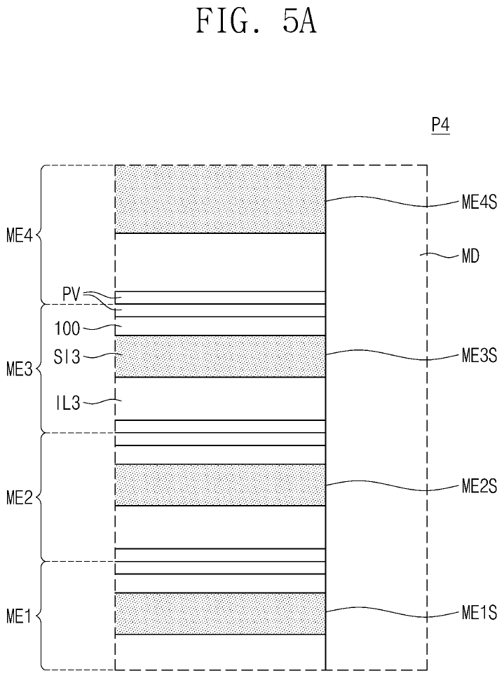

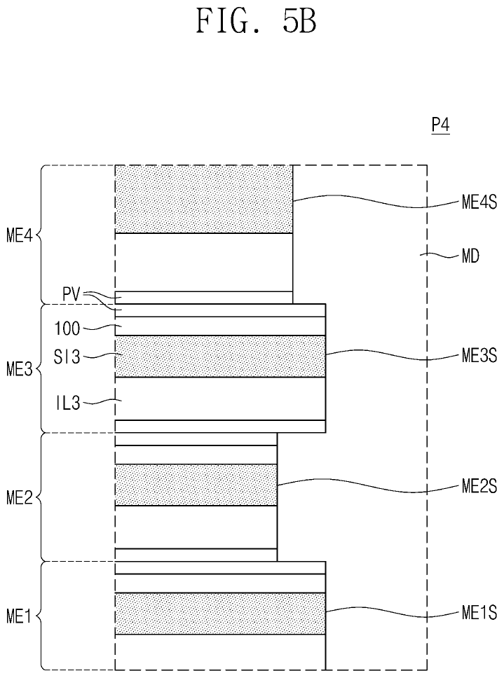

FIGS. 5A and 5B are enlarged sectional views illustrating a portion ‘P4’ of FIG. 1A.

In an embodiment, as shown in FIG. 5A, the first to fourth memory dies ME1 to ME4 may be formed to have side surfaces ME1S to ME4S that are vertically aligned with each other.

In another embodiment, as shown in FIG. 5B, the first to fourth memory dies ME1 to ME4 may be formed to have side surfaces ME1S to ME4S that are not vertically aligned with each other (i.e., may form a corrugated side surface). For example, in the fabrication process of the semiconductor package 1000, the first to fourth memory dies ME1 to ME4 may not be precisely placed at their desired positions, when the first to fourth memory dies ME1 to ME4 are sequentially stacked as shown in FIG. 6D, and in this case, the semiconductor package may have the same structure as shown in FIG. 5B.

FIGS. 6A to 6G are sectional views sequentially illustrating a process of fabricating the semiconductor package of FIG. 1A. For concise description, a previously described element may be identified by the same reference number without repeating an overlapping description thereof.

Referring to FIGS. 6A and 1B, the buffer die wafer BFW may be prepared. The buffer die wafer BFW may have a plurality of chip regions DR and a separation region SR therebetween. Each of the chip regions DR of the buffer die wafer BFW may have substantially the same structure as the buffer die BF as described with reference to FIGS. 1A to 5. The separation region SR may be a scribe lane region. The buffer die wafer BFW may include the first semiconductor substrate SI1. The first semiconductor substrate SI1 may include the first surface 10a and the second surface 10b, which are opposite to each other. First transistors (not shown) and a portion of the first interlayer insulating layer IL1 may be formed on the second surface 10b, and here, the portion of the first interlayer insulating layer IL1 may be formed to cover the first transistors. The portion of the first interlayer insulating layer IL1 and the first semiconductor substrate SI1 may be etched to form a first penetration hole, and the first penetration via TSV1 and the via insulating layer TL may be formed in the first penetration hole. The inner interconnection lines 200 and the first interlayer insulating layer IL1 may contact the first penetration via TSV1. The first lower conductive pads LCP1 and the passivation layer PV may be formed on the first interlayer insulating layer IL1. The first outer connection members SB1 may be connected to the first lower conductive pads LCP1. In an embodiment, each of the first outer connection members SB1 may be connected to a corresponding one of the first lower conductive pads LCP1. The buffer die wafer BFW may be placed on a carrier substrate CR, such that the first outer connection members SB1 is placed at a lower level or faces the carrier substrate CR, and then, the buffer die wafer BFW and the carrier substrate CR may be bonded with each other using an adhesive layer GL. The adhesive layer GL may be formed of or include at least one of an adhesive resin, a thermosetting resin, a thermoplastic resin, and a photo-curable resin.

A grinding or etch-back process may be performed on the first surface 10a of the first semiconductor substrate SI1 to remove a portion of the first semiconductor substrate SI1 and expose the via insulating layer TL. For example, the first surface 10a may be recessed to a level that is lower than an end portion of the first penetration via TSV1. In an embodiment, as a result of the grinding process, a thickness of the first semiconductor substrate SI1 may be reduced. The first penetration via TSV1 may include a protruding portion that is located at a higher level than the first surface 10a. The protection layer 100 may be formed on the first surface 10a. A chemical mechanical polishing (CMP) or etch-back process may be performed to remove at least a portion of the protection layer 100 and a portion of the via insulating layer TL and to expose the first penetration vias TSV1. The first upper conductive pads UCP1 and the passivation layer PV may be formed on the protection layer 100.

Referring to FIGS. 6B and 1B, a computing die wafer PIW may be prepared. The computing die wafer PIW may have the chip regions DR and the separation region SR therebetween. The chip regions DR of the computing die wafer PIW may be provided to have a structure corresponding to the computing die PI as described with reference to FIGS. 1A to 5. The separation region SR may be a scribe lane region. The computing die wafer PIW may include the second semiconductor substrate SI2. The second semiconductor substrate SI2 may include the first surface 10a and the second surface 10b, which are opposite to each other. First transistors (not shown) may be formed at the second surface 10b of the second semiconductor substrate SI2, and a portion of the second interlayer insulating layer IL2 may cover the first transistors formed at the second surface 10b of the second semiconductor substrate SI2. The portion of the second interlayer insulating layer IL2 and the second semiconductor substrate SI2 may be etched to form a second penetration hole, and then, the second penetration via TSV2 and the via insulating layer TL may be formed in the second penetration hole. The inner interconnection lines 200 and the second interlayer insulating layer IL2 may contact the second penetration via TSV2. The second lower conductive pads LCP2 and the passivation layer PV may be formed on the second interlayer insulating layer IL2.

The computing die wafer PIW may be bonded to the buffer die wafer BFW. Here, a direct bonding process or a hybrid copper bonding process may be performed to bond the buffer die wafer BFW to the computing die wafer PIW. In an embodiment, the direct boding process may include a direct copper bonding process (e.g., a Cu-to-Cu direct bonding process). In an embodiment, the hybrid copper bonding may refer to a Cu-to-Cu direct bonding along with oxide bonding simultaneously. The computing die wafer PIW may be placed such that the active surface of the computing die wafer PIW faces the buffer die wafer BFW. The second interlayer insulating layer IL2 and the second lower conductive pads LCP2 may contact the first semiconductor substrate SI1 and the first upper conductive pads UCP1, respectively. For example, the computing die wafer PIW and the buffer die wafer BFW are arranged such that the second lower conductive pads LCP2 contact the first upper conductive pads UCP1, respectively. After such arrangement of the computing die wafer PIW and the buffer die wafer BFW, a thermo-compression process or the like may be performed to bond the computing die wafer PIW to the buffer die wafer BFW in a direct bonding manner. The buffer die wafer BFW and the computing die wafer PIW may be directly bonded with each other by the first upper conductive pads UCP1 and the second lower conductive pads LCP2, and in an embodiment, the buffer die wafer BFW and the computing die wafer PIW may form an interface 300 therebetween. The interface 300 between the buffer die wafer BFW and the computing die wafer PIW may include an inorganic insulating material (e.g., silicon oxide) in a space between two adjacent ones of the first upper conductive pads UCP1 and in a space between two adjacent ones of the second lower conductive pads LCP2.

Referring to FIGS. 6C and 1B, a grinding or etch-back process may be performed on the first surface 10a of the second semiconductor substrate SI2 to remove a portion of the second semiconductor substrate SI2 and expose the via insulating layer TL. For example, the first surface 10a may be recessed to a level that is lower than an end portion of the second penetration via TSV2. In an embodiment, as a result of the grinding process, a thickness of the second semiconductor substrate SI2 may be reduced. The second penetration via TSV2 may include a protruding portion that is located at a higher level than the first surface 10a. The protection layer 100 may be formed on the first surface 10a. A CMP or etch-back process may be performed to remove at least a portion of the protection layer 100 and a portion of the via insulating layer TL and to expose the second penetration vias TSV2. The second upper conductive pads UCP2 and the passivation layer PV may be formed on the protection layer 100.

Referring to FIGS. 6D and 3, the memory dies M may be prepared. The memory dies M may include the first to fourth memory dies ME1 to ME4. Each of the first to fourth memory dies ME1 to ME4 may be prepared to include the third interlayer insulating layer IL3, the third penetration via TSV3, the via insulating layer TL, the third upper conductive pads UCP3, the third lower conductive pads LCP3, the protection layer 100, and the passivation layer PV, which are formed on the third semiconductor substrate SI3 by the method as described with reference to FIGS. 6A to 6C. Thereafter, a sawing process may be performed such that all of the first to fourth memory dies ME1 to ME4 have the same size. By contrast, the fourth memory die ME4 may be formed by performing the sawing process, while omitting the steps of forming the third penetration via TSV3, the via insulating layer TL, and the third upper conductive pads UCP3. For the formation of the fourth memory die ME4, the grinding process of reducing a thickness of the third semiconductor substrate SI3 may be omitted.

The first to fourth memory dies ME1 to ME4 may be stacked on the chip regions DR of the computing die wafer PIW. Here, as shown in FIG. 3, the second inner connection members SP2 may be interposed between the first to fourth memory dies ME1 to ME4. The second inner connection members SP2 may include solder balls or conductive bumps. In an embodiment, a flip-chip bonding method may be used to bond the second memory die ME2 to the first memory die ME1, bond the third memory die ME3 to the second memory die ME2, and bond the fourth memory die ME4 to the third memory die ME3.

The under fill UF may be provided to fill spaces between two adjacent memory dies of the first to fourth memory dies ME1 to ME4, as shown in FIG. 3. The under fill UF may be formed through a dispensing and curing process. The under fill UF may be formed of or include an epoxy resin and may protect the second inner connection members SP2.

When the first to fourth memory dies ME1 to ME4 are stacked, the first to fourth memory dies ME1 to ME4 may not be precisely formed at their desired positions. In this case, the side surfaces ME1S to ME4S of the first to fourth memory dies ME1 to ME4 may not be aligned with each other, as shown in FIG. 5B.

The stacked memory dies M may be bonded to the computing die wafer PIW through a thermo-compression process. Here, a direct bonding process or a hybrid copper bonding process may be performed to bond the first memory die ME1 to the computing die wafer PIW. The first memory die ME1 may be placed such that the active surface of the first memory die ME1 faces the computing die wafer PIW. The first memory die ME1 may be placed such that the third interlayer insulating layer IL3 contacts the second semiconductor substrate SI2 and the third lower conductive pads LCP3 contact the second upper conductive pads UCP2, respectively. For example, the first memory die ME1 and the computing die wafer PIW may be arranged such that the third lower conductive pads LCP3 contact the second upper conductive pads UCP2, respectively, and the third interlayer insulating layer IL3 contacts the second semiconductor substrate SI2. After such arrangement of the first memory die ME1 and the computing die wafer PIW, a thermo-compression process or the like may be performed to bond the first memory die ME1 to the computing die wafer PIW in the direct bonding manner. The computing die wafer PIW and the first memory die ME1 may be directly bonded with each other by using direct bonding between the second upper conductive pads UCP2 and the third lower conductive pads LCP3, and in an embodiment, the computing die wafer PIW and the first memory die ME1 may form an interface 400 therebetween. The interface 400 may be formed in a space between two adjacent ones of the second upper conductive pads UCP2 and in a space between two adjacent ones of the third lower conductive pads LCP3. The interface 400 may include an inorganic insulating material (e.g., silicon oxide).

Referring to FIGS. 6E and 6F, a thermo-compression process may be performed to bond the memory dies M to the computing die wafer PIW, and then, a casting process may be performed to form the mold layer MD covering a top surface of the computing die wafer PIW and side surfaces of the memory dies M. The mold layer MD may be formed of or include an insulating polymer, such as an epoxy molding compound (EMC). Thereafter, the buffer die wafer BFW may be separated from the adhesive layer GL and the carrier substrate CR.

Referring to FIG. 6G, a dicing process using a laser beam may be performed to remove the separation region SR, and as a result, a plurality of semiconductor packages 1000 may be formed. Each of the semiconductor packages 1000 may have substantially the same structure as the semiconductor package 1000 of FIG. 1A.

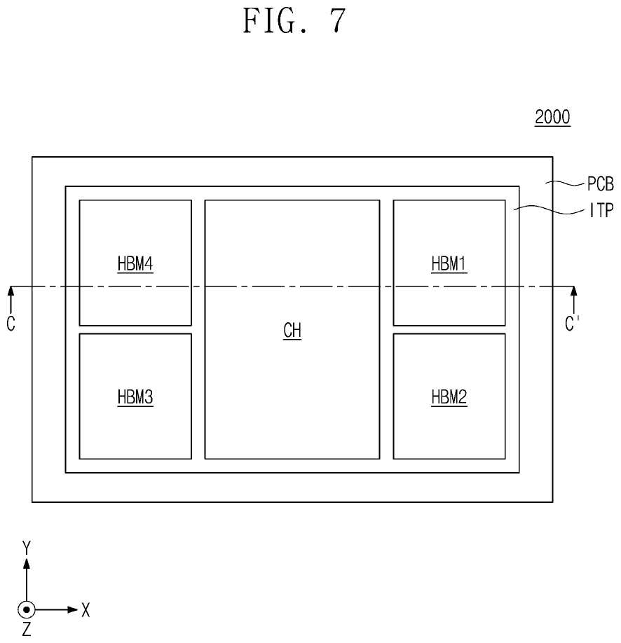

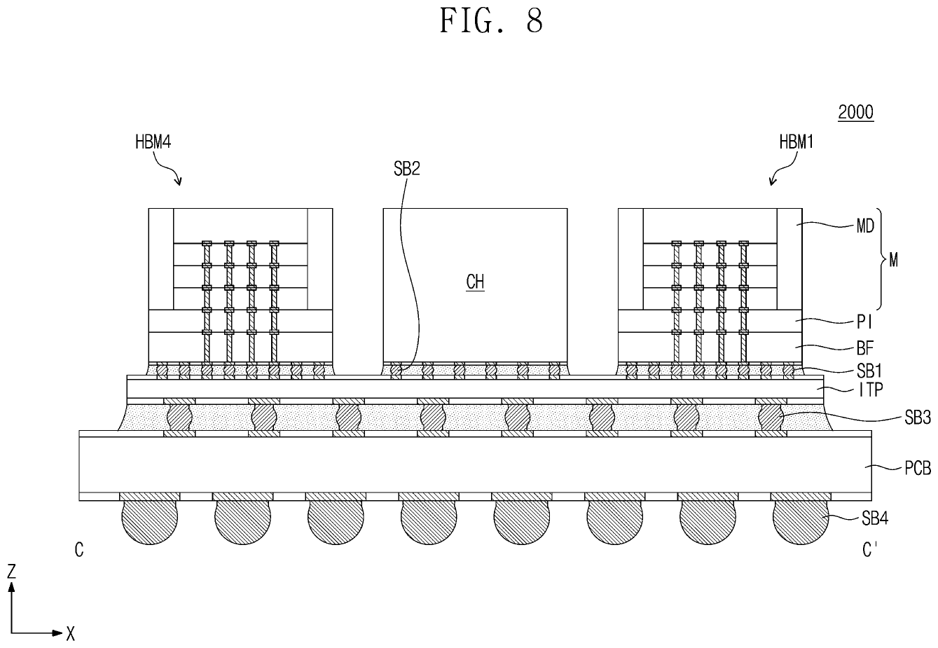

FIG. 7 is a plan view illustrating a semiconductor package according to an embodiment of the inventive concept. FIG. 8 is a sectional view taken along a line C-C′ of FIG. 7 to illustrate a semiconductor package according to an embodiment of the inventive concept.

Referring to FIGS. 7 and 8, in a semiconductor package 2000 according to the present embodiment, an interposer substrate ITP may be disposed on a package substrate PCB. In an embodiment, the package substrate PCB may be a double-sided or multi-layer printed circuit board. In an embodiment, the interposer substrate ITP may be formed of or include silicon. The interposer substrate ITP may be bonded to the package substrate PCB by third outer connection members SB3. Fourth outer connection members SB4 may be bonded to a bottom surface of the package substrate PCB. Four peripheral semiconductor chips HBM1 to HBM4 and one center semiconductor chip CH may be disposed on the interposer substrate ITP. The peripheral semiconductor chips HBM1 to HBM4 may be arranged in pairs on opposite sides of the center semiconductor chip CH. The four peripheral semiconductor chips HBM1 to HBM4 may include first to fourth peripheral semiconductor chips HBM1 to HBM4. The first to fourth peripheral semiconductor chips HBM1 to HBM4 and the center semiconductor chip CH may have substantially the same thickness.

The center semiconductor chip CH may be connected to the interposer substrate ITP through second outer connection members SB2. The center semiconductor chip CH may be an application specific integrated circuit (ASIC) chip or a system-on-chip. The center semiconductor chip CH may be referred to as a host or an application processor AP. The center semiconductor chip CH may include a memory controller, which is configured to control the memory dies M and the computing dies PI and execute a data input/output operation with the memory dies M and the computing dies PI. The memory controller may access the memory dies M and the computing dies PI in a direct memory access (DMA) manner. The interposer substrate ITP may include inner interconnection lines (not shown) connecting the center semiconductor chip CH to the first to fourth peripheral semiconductor chips HBM1 to HBM4.

The first to fourth peripheral semiconductor chips HBM1 to HBM4 may be connected to the interposer substrate ITP through the first outer connection members SB1. The first to fourth peripheral semiconductor chips HBM1 to HBM4 may be the same as or similar to the semiconductor package 1000 as described with reference to FIGS. 1A to 6G.

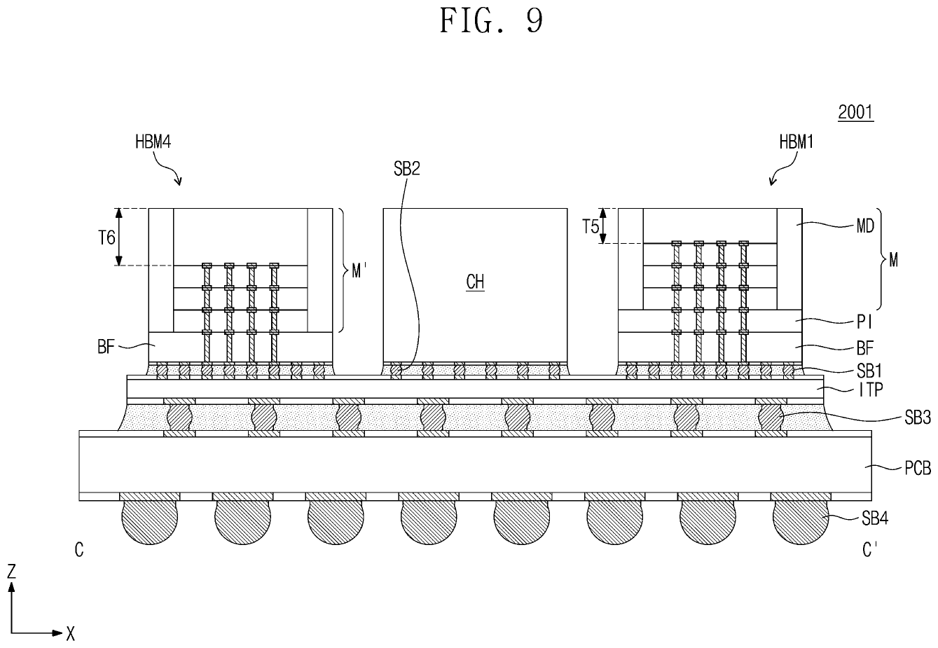

FIG. 9 is a sectional view taken along the line C-C′ of FIG. 7 to illustrate a semiconductor package according to an embodiment of the inventive concept.

Referring to FIGS. 7 and 9, in a semiconductor package 2001 according to the present embodiment, the interposer substrate ITP may be disposed on the package substrate PCB. In an embodiment, the package substrate PCB may be a double-sided or multi-layer printed circuit board. The interposer substrate ITP may be formed of or include silicon. The interposer substrate ITP may be bonded to the package substrate PCB by the third outer connection members SB3. The fourth outer connection members SB4 may be bonded to the bottom surface of the package substrate PCB. Four peripheral semiconductor chips HBM1 to HBM4 and one center semiconductor chip CH may be disposed on the interposer substrate ITP. The peripheral semiconductor chips HBM1 to HBM4 may be arranged in pairs on opposite sides of the center semiconductor chip CH, when viewed in a plan view.

The center semiconductor chip CH may be connected to the interposer substrate ITP through the second outer connection members SB2. The center semiconductor chip CH may be an application specific integrated circuit (ASIC) chip or a system-on-chip. The center semiconductor chip CH may be referred to as a host or an application processor AP. The center semiconductor chip CH may include a memory controller, which is configured to control the memory dies M and M′ and the computing dies PI and execute a data input/output operation with the memory dies M and M′ and the computing dies PI. The memory controller may access the memory dies M and M′ and the computing dies PI in a direct memory access (DMA) manner. The interposer substrate ITP may include inner interconnection lines (not shown) connecting the center semiconductor chip CH to the first to fourth peripheral semiconductor chips HBM1 to HBM4.

The first to fourth peripheral semiconductor chips HBM1 to HBM4 may be connected to the interposer substrate ITP through the first outer connection members SB1. For example, the first to third peripheral semiconductor chips HBM1 to HBM3 may have the same or similar structure as the semiconductor package 1000 as described with reference to FIGS. 1A to 6G. In an embodiment, the fourth peripheral semiconductor chip HBM4 may be a high bandwidth memory (HBM) chip, which has a structure similar to the semiconductor package 1000 but does not include a computing die. The first to fourth peripheral semiconductor chips HBM1 to HBM4 may be provided to have the same thickness as the center semiconductor chip CH. However, a thickness T6 of the uppermost one of the memory dies M′ of the fourth peripheral semiconductor chip HBM4 may be larger than a thickness T5 of the uppermost one of the memory dies M of the first to third peripheral semiconductor chips HBM1 to HBM3. However, the inventive concept is not limited to this example, and the first to fourth peripheral semiconductor chips HBM1 to HBM4 may have a structure that is the same as or different from the semiconductor package 1000 of FIG. 1A and may be provided in one of various possible combined manners.

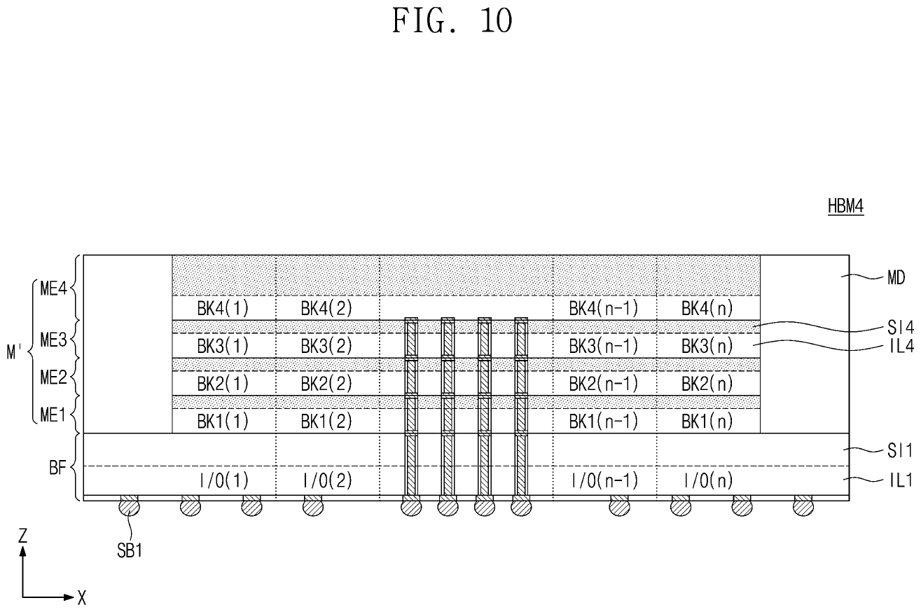

FIG. 10 is a sectional view of the fourth peripheral semiconductor chip of FIG. 9 according to an embodiment of the inventive concept.

Referring to FIGS. 9 and 10, in the fourth peripheral semiconductor chip HBM4, the memory dies M′ may be stacked on the buffer die BF. The buffer die BF may include the input/output terminals I/O. The memory dies M′ may be the same as or similar to the memory dies M of FIG. 1A. In an embodiment, the memory dies M′ may include the first to fourth memory dies ME1 to ME4. Each of the first to fourth memory dies ME1 to ME4 may include fourth semiconductor substrates SI4 and memory blocks BK1 to BK4. The memory blocks BK1 to BK4 may be provided at the fourth semiconductor substrates SI4 of each of the first to fourth memory dies ME1 to ME4. The first to fourth memory blocks BK1 to BK4 of the first to fourth memory dies ME1 to ME4 may be controlled by an external controller through the input/output terminals I/O of the buffer die BF.

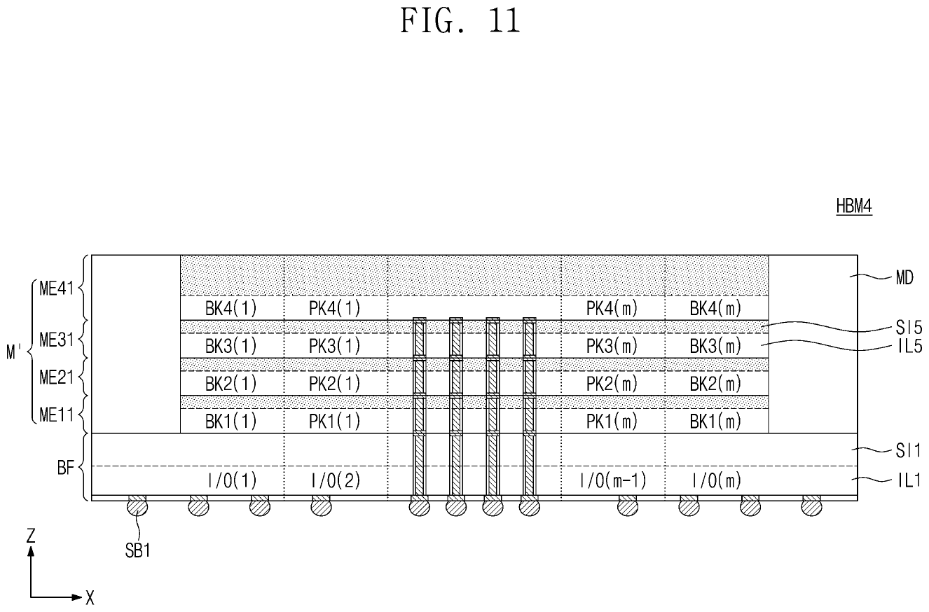

FIG. 11 is a sectional view of the fourth peripheral semiconductor chip of FIG. 9 according to an embodiment of the inventive concept.

Referring to FIGS. 9 and 11, in the fourth peripheral semiconductor chip HBM4, the memory dies M′ may be stacked on the buffer die BF. The buffer die BF may include the input/output terminals I/O. In an embodiment, the memory dies M′ may include first to fourth memory dies ME11 to ME41. The first to fourth memory dies ME11 to ME41 may include fifth semiconductor substrates SI5 and memory blocks BK1 to BK4. The memory blocks BK1 to BK4 may be provided at the fifth semiconductor substrates SI5 of each of the first to fourth memory dies ME11 to ME41. Furthermore, the first to fourth memory dies ME11 to ME41 may further include computing blocks PK1 to PK4, respectively. Each of the computing blocks PK1 to PK4 may be provided at the fifth semiconductor substrate SI5 of a corresponding one of the first to fourth memory dies ME11 to ME41. The first to fourth computing blocks PK1 to PK4 may be provided inside the first to fourth memory blocks BK1 to BK4, such that they are adjacent and parallel to the first to fourth memory blocks BK1 to BK4. The first to fourth computing blocks PK1 to PK4 may be connected to the first to fourth memory blocks BK1 to BK4, respectively. The first to fourth computing blocks PK1 to PK4 may be configured to process respective data, which are received from the first to fourth memory blocks BK1 to BK4, and to store the results in the first to fourth memory blocks BK1 to BK4, respectively. The first to fourth memory blocks BK1 to BK4 and the first to fourth computing blocks PK1 to PK4 of the first to fourth memory dies ME11 to ME41 may be controlled by an external controller through the input/output terminals I/O of the buffer die BF.

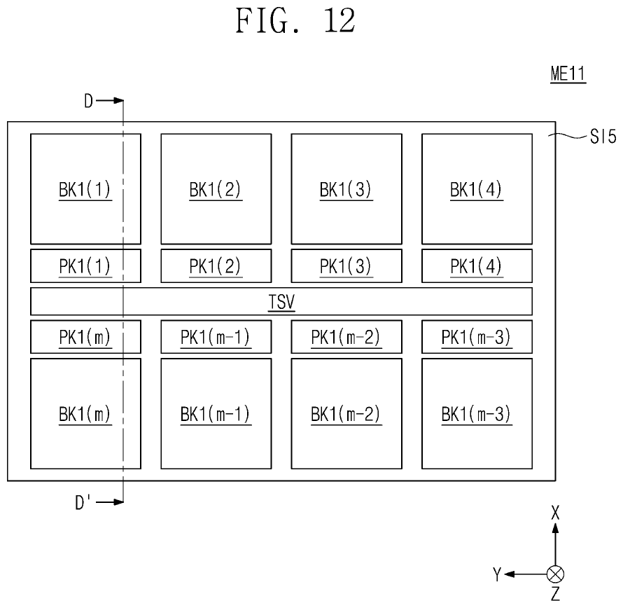

FIG. 12 is a plan view illustrating an example of a first memory die of FIG. 11. A section taken along a line D-D′ of FIG. 12 may correspond to the first memory die ME11 of FIG. 11.

FIG. 12 is a plan view illustrating the first memory die ME11 of the first to fourth memory dies ME11 to ME41. The penetration via region TSV, m first memory blocks BK1, and m first computing blocks PK1 may be disposed on the fifth semiconductor substrate SI5 of the first memory die ME11. The first memory blocks BK1 may be provided to enclose the penetration via region TSV. The first computing blocks PK1 may be provided inside the first memory blocks BK1, such that they are adjacent and parallel to the first memory blocks BK1. In an embodiment, the memory blocks BK1 may include first to mₜₕ memory blocks BK1(1) to BK1(m). The first to mₜₕ memory blocks BK1(1) to BK1(m) may be arranged in two rows extending in a third direction Y, and when viewed in a plan view, the penetration via region TSV and first computing blocks PK1 may be disposed in a space between the two rows of the first to mₜₕ memory blocks BK1(1) to BK1(m). The first computing blocks PK1 may be connected to the first memory blocks BK1, respectively. For example, the first computing blocks PK1 may include first to mₜₕ computing blocks PK1(1) to PK1(m), which are connected to the first to mₜₕ memory blocks BK1(1) to BK1(m), respectively. The first computing blocks PK1 may be configured to process respective data, which are received from the first memory blocks BK1, and to store the results in the first memory blocks BK1, respectively. However, the planar structure of the first memory die ME11 may not be limited to that shown in FIG. 12 and may be variously modified. Each of the second to fourth memory dies ME21 to ME41 may also have the same or similar structure as the first memory die ME11 as described with reference to FIG. 12.

In a semiconductor package according to an embodiment of the inventive concept, a computing die may be placed on a buffer die using conductive pads, and memory dies may be stacked on the computing die. Data, which are transmitted from the memory dies, may be processed by the computing die, and then, the processed data may be stored in the memory dies. The computing die may be separately placed on a bottom surface of the memory die, and in this case, the memory dies may have a reduced chip size and an increased memory capacity. Thus, it may be possible to realize a highly efficient high-performance semiconductor package.

While example embodiments of the inventive concept have been particularly shown and described, it will be understood by one of ordinary skill in the art that variations in form and detail may be made therein without departing from the spirit and scope of the attached claims.

1. A semiconductor package comprising:
a buffer die;
a computing die on the buffer die;
a plurality of memory dies vertically stacked on each other to form a memory stack, wherein the memory stack is disposed on the computing die, wherein the buffer die, the computing die, and the memory stack are vertically stacked on each other, and wherein the computing die is disposed in a space between the buffer die and the memory stack; and
a mold layer covering the computing die and the plurality of memory dies,
wherein the buffer die comprises a plurality of outer connection members,
wherein the computing die comprises a plurality of computing blocks,
wherein each of the plurality of memory dies comprises a plurality of memory blocks, and
wherein the plurality of computing blocks are configured to process data received from the plurality of memory blocks and to store the processed results in the plurality of memory blocks.

2. The semiconductor package of claim 1,
wherein each of the buffer die and the computing die has a first width in a first direction,
wherein each of the plurality of memory dies has a second width in the first direction, and
wherein the second width is smaller than the first width.

3. The semiconductor package of claim 1,
wherein the plurality of memory dies comprise first to fourth memory dies that are vertically stacked on each other,
wherein the buffer die has a first thickness,
wherein the computing die has a second thickness,
wherein each of the first to third memory dies has a third thickness,
wherein the first thickness is larger than the second thickness, and
wherein the third thickness is smaller than a sum of the first and second thicknesses.

4. The semiconductor package of claim 3,
wherein the fourth memory die has a fourth thickness, and
wherein the fourth thickness is larger than the third thickness.

5. The semiconductor package of claim 3,
wherein each of the buffer die, the computing die, and the first to third memory dies comprises a penetration via, and
wherein the fourth memory die is provided without a penetration via.

6. The semiconductor package of claim 1,
wherein a side surface of the buffer die is vertically aligned to a side surface of the computing die.

7. The semiconductor package of claim 1,
wherein side surfaces of the plurality of memory dies form a corrugated side surface.

8. The semiconductor package of claim 1,
wherein an active surface of the computing die faces toward the buffer die and contacts the buffer die.

9. The semiconductor package of claim 1,
wherein the buffer die further comprises:
a first semiconductor substrate, on which the plurality of outer connection members are disposed;
a first interlayer insulating layer covering the first semiconductor substrate;
a plurality of first penetration vias penetrating the first semiconductor substrate and connected to the computing die;
a plurality of first upper conductive pads disposed at a top surface of the first semiconductor substrate; and
a plurality of first lower conductive pads disposed at a bottom surface of the first interlayer insulating layer, wherein each of the first lower conductive pads connects a corresponding one of the plurality of outer connection members to a corresponding one of the plurality of first penetration vias.

10. The semiconductor package of claim 9,
wherein the computing die further comprises:
a second semiconductor substrate at which the plurality of computing blocks are disposed;
a second interlayer insulating layer covering the second semiconductor substrate and the plurality of computing blocks;
a plurality of second penetration vias penetrating the second semiconductor substrate and connected to a lowermost memory die of the plurality of memory dies;
a plurality of second upper conductive pads disposed at a top surface of the second semiconductor substrate; and
a plurality of second lower conductive pads disposed at a bottom surface of the second interlayer insulating layer and connected to the buffer die.

11. The semiconductor package of claim 10,
wherein the plurality of first upper conductive pads contact the plurality of second lower conductive pads, respectively, and
wherein the plurality of first upper conductive pads and the plurality of first lower conductive pads are formed of the same material.

12. The semiconductor package of claim 10,
wherein each of the plurality of memory dies further comprises:
a third semiconductor substrate at which the plurality of memory blocks are disposed;
a third interlayer insulating layer covering the third semiconductor substrate;
a plurality of third penetration vias penetrating the third semiconductor substrate and connected to the computing die;
a plurality of third upper conductive pads disposed at a top surface of the third semiconductor substrate; and
a plurality of third lower conductive pads disposed at a bottom surface of the third interlayer insulating layer.

13. The semiconductor package of claim 12,
wherein the plurality of second upper conductive pads contact the plurality of third lower conductive pads, respectively, and
wherein the plurality of second upper conductive pads and the plurality of third lower conductive pads are formed of the same material.

14. The semiconductor package of claim 1, further comprising:
an interposer substrate disposed below the buffer die;
a package substrate disposed below the interposer substrate, wherein the buffer die, the interposer substrate, and the package substrate are vertically stacked on each other, and wherein the interposer substrate is disposed in a space between the buffer die and the package substrate; and
a first semiconductor chip mounted on the interposer substrate, wherein the first semiconductor chip is horizontally adjacent to the buffer die.

15. A semiconductor package comprising:
a buffer die;
a computing die on the buffer die;
a plurality of memory dies stacked on the computing die; and
a mold layer covering the computing die and memory dies,
wherein the buffer die comprises a plurality of outer connection members,
wherein the computing die comprises a plurality of computing blocks,
wherein each of the plurality of memory dies comprises a plurality of memory blocks,
wherein the plurality of computing blocks are configured to process data received from the plurality of memory blocks and to store the processed results in the plurality of memory blocks,
wherein the buffer die further comprises:
a first semiconductor substrate, on which the plurality of outer connection members are disposed, and
a plurality of first upper conductive pads disposed at a top surface of the first semiconductor substrate,
wherein the computing die further comprises:
a second semiconductor substrate, at which the plurality of computing blocks are disposed,
a second interlayer insulating layer covering the second semiconductor substrate, and
a plurality of second lower conductive pads disposed at a bottom surface of the second interlayer insulating layer and are connected to the buffer die,
wherein the plurality of first upper conductive pads contact the plurality of second lower conductive pads, respectively,
wherein the plurality of memory dies comprise first to fourth memory dies which are vertically stacked on each other,
wherein the buffer die has a first thickness,
wherein the computing die has a second thickness,
wherein each of the first to third memory dies has a third thickness,
wherein the first thickness is larger than the second thickness, and
wherein the third thickness is smaller than a sum of the first and second thicknesses.

16. The semiconductor package of claim 15, further comprising:
a plurality of first inner connection members disposed in a space between the computing die and the first memory die; and
an under fill filling the space between the computing die and the first memory die,
wherein the computing die further comprises:
a plurality of second upper conductive pads disposed at a top surface of the second semiconductor substrate,
wherein each of the first to third memory dies further comprises:
a third semiconductor substrate,
a third interlayer insulating layer covering the third semiconductor substrate, and
a plurality of third lower conductive pads disposed at a bottom surface of the third interlayer insulating layer, and
wherein the plurality of first inner connection members are placed between the plurality of second upper conductive pads and the plurality of third lower conductive pads of the first memory die and each of the first inner connection members connects a corresponding one of the plurality of second upper conductive pads to a corresponding one of the plurality of third lower conductive pads.

17. A semiconductor package comprising:
a package substrate;
an interposer substrate on the package substrate; and
a first semiconductor chip, a second semiconductor chip, and a third semiconductor chip, which are disposed on the interposer substrate and are horizontally arranged in a first direction,
wherein the first semiconductor chip comprises:
a first buffer die;
a first computing die vertically disposed on the first buffer die;
a plurality of first memory dies vertically stacked on each other to form a first memory stack, wherein the first memory stack is disposed on the first computing die, wherein the first buffer die, the first computing die, and the first memory stack are vertically stacked on each other, and where the first computing die is disposed in a space between the first buffer die and the first memory stack; and
a first mold layer covering the first computing die and the plurality of first memory dies,
wherein the first buffer die comprises a plurality of first outer connection members,
wherein the first computing die comprises a plurality of first computing blocks,
wherein each of the plurality of first memory dies comprises a plurality of first memory blocks, and
wherein the plurality of first computing blocks are configured to process data received from the plurality of first memory blocks and to store the processed results in the plurality of first memory blocks.

18. The semiconductor package of claim 17,
wherein the second semiconductor chip comprises:
a second buffer die;
a plurality of second memory dies stacked on each other to form a second memory stack, wherein the second memory stack is disposed on the second buffer die; and
a second mold layer covering the plurality of second memory dies,
wherein the second buffer die comprises a plurality of second outer connection members, and
wherein each of the plurality of second memory dies comprises a plurality of second memory blocks.

19. The semiconductor package of claim 18,
wherein each of the plurality of second memory dies further comprise a plurality of second computing blocks which are adjacent to the plurality of second memory blocks, and
wherein the plurality of second computing blocks are configured to process data received from the plurality of second memory blocks and to store the processed results in the plurality of second memory blocks.

20. The semiconductor package of claim 18,
wherein an uppermost memory die in the first semiconductor chip has a fifth thickness,
wherein an uppermost memory die in the second semiconductor chip has a sixth thickness, and
wherein the sixth thickness is larger than the fifth thickness.

21. (canceled)
